(19) United States
(12) Patent Application Publication
(10) Pub. No.: US 2006/0186538 A1
(43) Pub. Date: Aug. 24, 2006

(54) Land grid array package

(75) Inventor: Takuya Suzuka, Kyoto (JP)

Correspondence Address: ARMSTRONG, KRATZ, QUINTOS, HANSON & BROOKS, LLP, 1725 K STREET, NW, SUITE 1000, WASHINGTON, DC, 20006, US

(73) Assignees: Sanyo Electric Co., Ltd., Moriguchi-shi (JP); Sanyo Tuner Industries Co., Ltd., Daito-shi (JP)

(21) Appl. No.: 10/548,547

(22) PCT Filed: Nov. 11, 2004
(86) PCT No.: PCT/JP04/17131

§ 371 Date: Sep. 13, 2005

(30) Foreign Application Priority Data
Nov. 19, 2003 (JP) 2003-390004

(51) Int. Cl. H01L 23/48; H01L 23/52; H01L 29/40

(52) U.S. Cl. 257/737

(57) ABSTRACT

A land grid array package has a construction in which a device-side ground electrode 6 and a substrate-side ground electrode 9, as well as device-side peripheral electrodes 7 and substrate-side peripheral electrodes 10 are soldered by eutectic solder 16. The land grid array package is characterized in that one or more gas-vent through holes 15 passing through a package substrate 3 are formed within a soldering region 18 of the device-side ground electrode 6. Thus, a land grid array package that can prevent short circuits or disconnections is provided.

### TECHNICAL FIELD

The present invention relates to land grid array packages, and more particularly to land grid array packages used for wireless communication modules.

### BACKGROUND ART

Recently, in order to increase packaging density and achieve size reduction etc. of electronic devices, new forms of semiconductor packages have been proposed such as ball grid arrays and land grid arrays, which are leadless packages and in which contact electrodes are made in grid form on back faces of the packages. In particular, those of the land grid array type are often used for high-frequency ICs or high-power ICs.

The high-frequency ICs have such a construction in which a large-area ground electrode (die pad) is formed in a central region of the back side of the package and the entire ground electrode is subjected to soldering. Such a construction is employed for the purpose of stabilizing ground potential and maintaining good high-frequency performance by soldering (or making electrical connection by) as large an area as possible. (See, for example, Japanese Published Unexamined Patent Application No. 2002-299491.)

A problem with the above-described conventional construction, however, is that disconnections and short circuits occur at power supply electrodes or the like formed in the periphery of the ground electrode. Specifically, it is believed that such a problem is caused for the following reasons.

A package construction of the land grid array package is as follows. As illustrated in FIG. 12, an IC chip 50 for land grid array package includes a central region provided with a device-side ground electrode 51 having a large area, and a peripheral region provided with device-side power supply electrodes 52a, 52b, etc. having a small area; on the other hand, a package substrate 53 includes a central region provided with a substrate-side ground electrode 54 having a large area, and a peripheral region provided with substrate-side power supply electrodes 55a, 55b, etc. having a small area. The device-side ground electrode 51 is electrically connected to the substrate-side ground electrode 54 and the device-side power supply electrodes 52a, 52b are electrically connected to the substrate-side power supply electrodes 55a, 55b by solders 56, 57a, and 57b, respectively.

As discussed above, in order to maintain good high-frequency performance, it is necessary to solder (electrically connect) the ground electrodes 51 and 54 by as large an area as possible.

For this reason, soldering between the ground electrodes 51 and 54 needs to be performed by applying a large amount of solder paste onto the substrate-side ground electrode 54 of the package substrate 53; however, when soldering is carried out in this manner, the IC chip 50 is elevated due to the surface tension of the solder paste during solder reflow and the gas generation caused by evaporation of flux in the solder paste or the like. In particular, the effect of the surface tension and the gas accumulation effect due to the gas generation concentrate in the central region of the IC chip 50. As a result, as illustrated in FIG. 12, the IC chip 50 for land grid array package is mounted inclined with respect to the package substrate 53. Consequently, such problems arise that short circuits occur because the solder paste is pressed between the device-side power supply electrode 52a and the substrate-side power supply electrode 55a and that disconnections occur between the device-side power supply electrode 52b and the substrate-side power supply electrode 55b due to an insufficiency of the solder paste.

The present invention has been accomplished in view of the foregoing circumstances, and an object of the invention is to provide a land grid array package that prevents short circuits or disconnections from occurring by inhibiting an IC chip for land grid array package from being mounted inclined with respect to a package substrate.

### DISCLOSURE OF THE INVENTION

The invention as set forth in claim 1 is a land grid array package comprising a semiconductor device in which a device-side center electrode is formed in a substantially central region of its back side and a plurality of device-side peripheral electrodes are formed in a periphery of the device-side center electrode, and a package substrate in which a substrate-side center electrode is provided at a position corresponding to the device-side center electrode and a plurality of substrate-side peripheral electrodes are formed at positions that are in a periphery of the substrate-side center electrode and correspond to the device-side peripheral electrodes, the device-side center electrode and the device-side peripheral electrodes being soldered to the substrate-side center electrode and the substrate-side peripheral electrodes, respectively, by one or more soldered portions, the land grid array package characterized in that: one or more gas-vent through holes passing through the package substrate are formed within a soldering region of the substrate-side center electrode.

When the one or more gas-vent through holes passing through the package substrate are formed within the substrate-side center electrode, it is possible to prevent the semiconductor device from being elevated even if gas generation occurs during solder reflow, because the gas can be discharged outside through the one or more gas-vent through holes. Accordingly, the semiconductor device is prevented from being mounted inclined with respect to the package substrate. Therefore, it is possible to prevent the short circuits due to the solder paste being pressed between the device-side peripheral electrodes and the substrate-side peripheral electrodes and the disconnections due to the insufficiency of solder paste between the device-side peripheral electrodes and the substrate-side peripheral electrodes.

In addition, since the one or more gas-vent through holes are formed within the soldering region in the substrate-side center electrode, gas discharging is carried out more smoothly.

The invention as set forth in claim 2 is characterized in that, in the invention as set forth in claim 1, the soldered portion in which the device-side center electrode and the substrate-side center electrode are soldered exists at a location within the soldering region other than a location in which the one or more gas-vent through holes exist.

The above-described construction makes it possible to avoid the drawbacks of gas discharge hindrance caused by the solder paste being plugged into the one or more gas-vent through holes and of short circuits caused by the solder paste coming out to the back side through the one or more gas-vent through holes; therefore, the foregoing operations and effects can be exhibited more effectively.

The invention as set forth in claim 3 is characterized in that, in the invention as set forth in claim 1 or 2, the one or more gas-vent through holes are a plurality of gas-vent through holes and arranged within the soldering region so that their distribution density becomes uniform, and the one or more soldered portions are a plurality of soldered portions and are arranged within the soldering region so that their distribution density becomes uniform.

When a plurality of gas-vent through holes are arranged within the soldering region uniformly, the gas generated in any location can be discharged outside through the gas-vent through holes smoothly. In addition, since there are a plurality of separate soldered portions, the surface tension in each of the soldered portion reduces. For these reasons, it is possible to more effectively prevent the semiconductor device from being elevated and to more effectively prevent the semiconductor device from being mounted inclined with respect to the package substrate.

Moreover, since the soldered portions are arranged so that their distribution density is uniform within the soldering region, the distances between the soldered portions become short. Therefore, stabilization of the ground potential is achieved, making it possible to maintain good high-frequency performance.

The invention as set forth in claim 4 is characterized in that, in the invention as set forth in claim 3, the gas-vent through holes and the soldered portions are arranged in a substantially grid pattern within the soldering region. Although this claim is to illustrate one example in which the gas-vent through holes and the soldered portions are arranged uniformly within the soldering region, the present invention is not limited to such a construction.

The invention as set forth in claim 5 is characterized in that, in the invention as set forth in any one of claims 1 through 4, the semiconductor device is a high-frequency IC chip.

The invention as set forth in claim 6 is characterized in that, in the invention as set forth in any one of claims 1 through 5, the device-side center electrode and the substrate-side center electrode are ground electrodes.

The invention as set forth in claim 7 is characterized in that, in the invention as set forth in any one of claims 1 through 6, each of the device-side peripheral electrodes and the substrate-side peripheral electrodes are composed of power supply electrodes, ground electrodes, or signal electrodes.

The invention as set forth in claim 8 is characterized in that, in the invention as set forth in any one of claims 1 through 7, the one or more soldered portions are formed so as to have substantially the same size as the size of the substrate-side peripheral electrodes.

With the above-described construction, the pressure applied to each solder paste becomes uniform when the semiconductor device is placed on the solder paste, making it possible to prevent the semiconductor device from being mounted inclined with respect to the package substrate more effectively and exhibit the operations and effects further.

### BRIEF DESCRIPTION OF THE DRAWINGS

FIG. 1 is a plan view of a package substrate used for a land grid array package according to the best mode of the present invention.

FIG. 2 is a back side view of an IC chip used for the land grid array package according to the best mode of the present invention.

FIG. 3 is a cross-sectional view illustrating a manufacturing process for the land grid array package according to the best mode of the present invention.

FIG. 4 is a cross-sectional view illustrating the land grid array package according to the best mode of the present invention.

FIG. 5 is a plan view of Package B of the invention, illustrating the manner in which solder paste is applied, and disconnections or short circuit defects after solder reflow.

FIG. 6 is a plan view of Package C of the invention, illustrating the manner in which solder paste is applied, and disconnections or short circuit defects after solder reflow.

FIG. 7 is a plan view of Comparative Package X, illustrating the manner in which solder paste is applied, and disconnections or short circuit defects after solder reflow.

FIG. 8 is a plan view of Comparative Package Y, illustrating the manner in which solder paste is applied, and disconnections or short circuit defects after solder reflow.

FIG. 9 is a plan view of Package A of the invention, illustrating the manner in which solder paste is applied, and disconnections or short circuit defects after solder reflow.

FIG. 10 is a plan view a modified example of a package of the invention, illustrating the manner in which solder paste is applied.

FIG. 11 is a plan view of a modified example of a Comparative Package, illustrating the manner in which solder paste is applied.

FIG. 12 is a cross-sectional view of a conventional land grid array package.

### BEST MODE FOR CARRYING OUT THE INVENTION

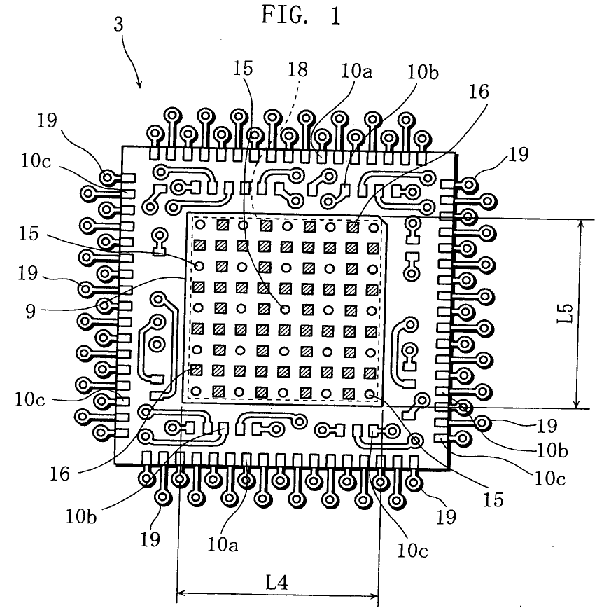

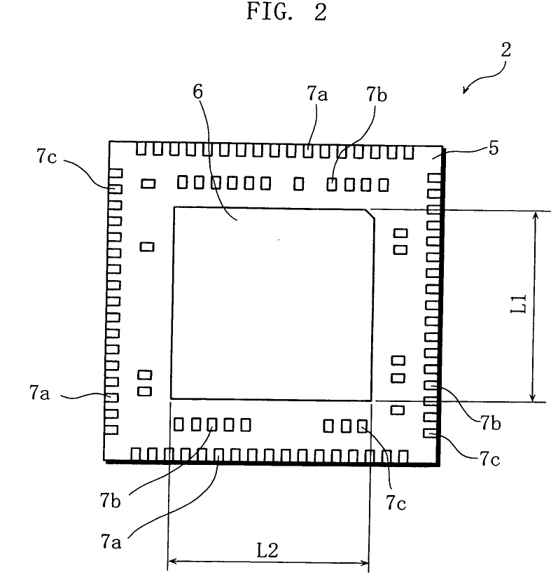

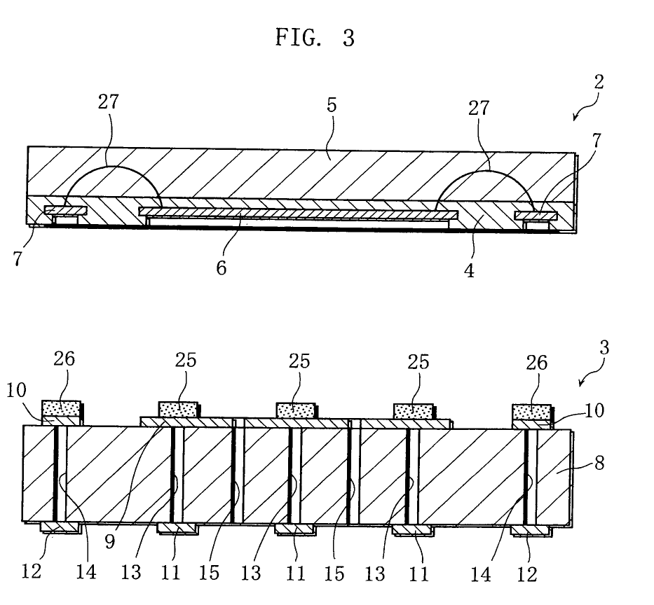

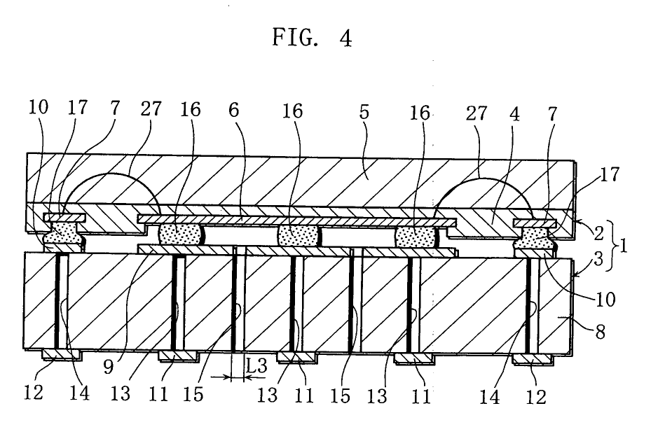

The best mode for carrying out the invention will be described with reference to FIGS. 1 to 4. FIG. 1 is a plan view of a package substrate used for a land grid array package according to the best mode of the present invention. FIG. 2 is a back side view of an IC chip used for the land grid array package according to the best mode of the present invention. FIG. 3 is a cross-sectional view illustrating a manufacturing process for the land grid array package according to the best mode of the present invention. FIG. 4 is a cross-sectional view illustrating the land grid array package according to the best mode of the present invention. It should be noted that various changes and modifications to the present invention may be made as long as such changes and variations fall within the scope of the invention.

As shown in FIG. 4, a land grid array package 1 of the present invention comprises an IC chip (5.15 to 5.35 GHz, high-frequency IC) 2 for land grid array package, and a package substrate 3.

The IC chip 2 has a semiconductor portion 4 made of gallium arsenide (GaAs). A sealing portion 5, for sealing the semiconductor portion 4, that is formed of such a material as glass epoxy resin is formed on one surface of the semiconductor portion 4. Provided in the central region of the other surface of the semiconductor portion 4 is a device-side ground electrode (device-side center electrode) 6 formed by a gold plating method, and provided in the peripheral region of the other surface of the semiconductor portion 4 are device-side peripheral electrodes 7 formed by a gold plating method. The device-side peripheral electrodes 7 and the device-side ground electrode 6 are electrically connected by wires 27. As illustrated in FIG. 2, the device-side ground electrode 6 forms a substantially square shape having L1 and L2 of 6 mm. The device-side peripheral electrodes 7 are located around the device-side ground electrode 6 and are constituted by a plurality of device-side power supply electrodes 7a, a plurality of device-side ground electrodes 7b, and a plurality of device-side signal electrodes 7c. (Note that, in FIG. 2, only some of the device-side power supply electrodes 7a, the device-side ground electrodes 7b, and the device-side signal electrodes 7c are identified by reference characters, and reference characters are omitted the rest of them.)

The package substrate 3 has a body portion 8 formed of a material such as glass epoxy resin. In the body portion 8, a substrate-side ground electrode (substrate-side center electrode) 9 made of copper is formed at a position (central region) corresponding to the device-side ground electrode 6 (central region), while substrate-side peripheral electrodes 10 made of copper are formed at positions corresponding to the device-side peripheral electrodes 7 (peripheral region). In the body portion 8, first outlet electrodes 11 and second outlet electrodes 12 for connection to outside are formed, and the first outlet electrodes 11 are electrically connected to the substrate-side ground electrode 9 via feedthrough holes (through holes) 13 for connection to outside, while the second outlet electrodes 12 are electrically connected to the substrate-side peripheral electrodes 10 via feedthrough holes (through holes) 14 for connection to outside. In the substrate-side ground electrode 9, gas-vent through holes 15 (diameter L3=0.3 mm) are formed for releasing outside quickly the gas generated due to, for example, the evaporation of flux in solder paste during solder reflow. In addition, the device-side ground electrode 6 and the device-side peripheral electrodes 7 are electrically connected to the substrate-side ground electrode 9 and the substrate-side peripheral electrodes 10, respectively, by eutectic solder 16, 17.

Here, the substrate-side ground electrode 9, as illustrated in FIG. 1, forms a substantially square shape having L4 and L5 of 6 mm. Moreover, numerous gas-vent through holes 15 are formed in a grid pattern within a soldering region 18 (which refers to a virtual region formed by the line connecting the outermost periphery of the eutectic solder 16) in the substrate-side ground electrode 9, and the eutectic solder 16 exists in a grid pattern within a location in which the gas-vent through holes 15 are not formed. It should be noted that, taking into consideration that the diameter of each gas-vent through hole 15 is 0.3 mm, the number of the gas-vent through holes 15 is 25, and the length of one side of the substantially square-shaped substrate-side ground electrode 9 is 6 mm, the proportion of the gas-vent through holes 15 to the substrate-side ground electrode 9 can be calculated by Equation 1 below.
0.15×0.15×3.14×25÷(6×6)×100≈4.9% (Eq. 1)

The substrate-side peripheral electrodes 10 are located around the substrate-side ground electrode 9 and are constituted by a plurality of substrate-side power supply electrodes 10a, a plurality of substrate-side ground electrodes 10b, and a plurality of substrate-side signal electrodes 10c (note that in FIG. 1, only some of the substrate-side power supply electrodes 10a, the substrate-side ground electrodes 10b, and the substrate-side signal electrode 10c are identified by reference characters, and reference characters are omitted for the rest of them). Outlet terminals 19 connected to the substrate-side peripheral electrodes 10 are provided in the periphery of the package substrate 3.

Herein, the above-described land grid array package may be fabricated as follows; as illustrated in FIG. 3, solder paste 25 is applied onto the substrate-side ground electrode 9 of the package substrate 3 in a grid pattern (in the same shape as the eutectic solder 16 shown in FIG. 1), and solder paste 26 is applied onto the substrate-side peripheral electrodes 10 of the package substrate 3. This solder paste applying process may be carried out using a metal mask or the like. Next, after placing the IC chip 2 on the substrate-side ground electrode 9, solder was reflowed using a solder reflow furnace.

### EXAMPLE 1

The above-described land grid array package according to the best mode for carrying out the invention was employed as Example 1.

The land grid array package thus fabricated is hereafter referred to as Package A of the invention.

### EXAMPLE 2

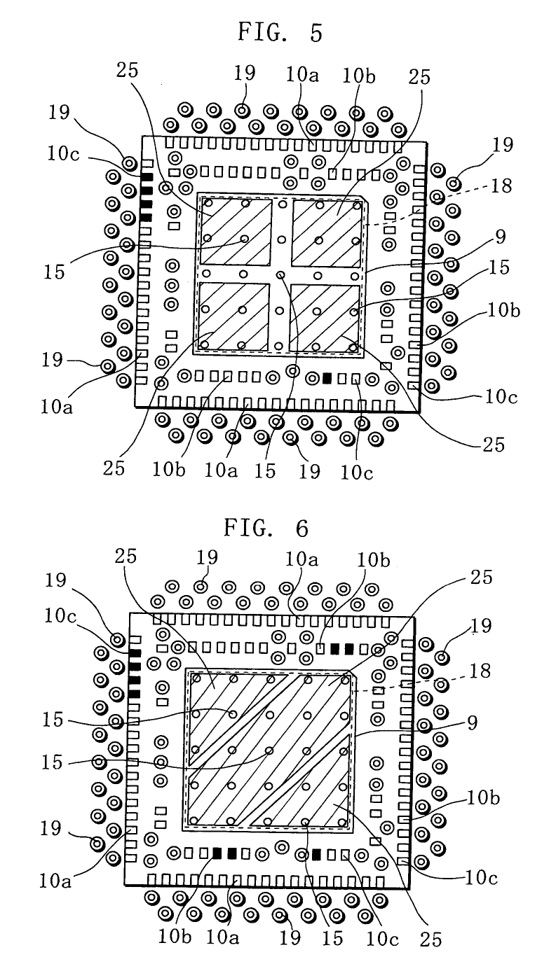

A land grid array package was fabricated in the same manner as in Example 1 above except that solder paste 25 was applied forming four separate squared shapes as illustrated in FIG. 5.

The land grid array package thus fabricated is hereafter referred to as Package B of the invention.

It should be noted that, in FIG. 5, mentioned above, and FIGS. 6 to 9, which will be referred to later, the leads of the outlet terminals 19 are omitted for simplicity in illustration.

### EXAMPLE 3

A land grid array package was fabricated in the same manner as in Example 1 above except that solder paste 25 was applied forming three separate regions as illustrated in FIG. 6.

The land grid array package thus fabricated is hereafter referred to as Package C of the invention.

### COMPARATIVE EXAMPLE 1

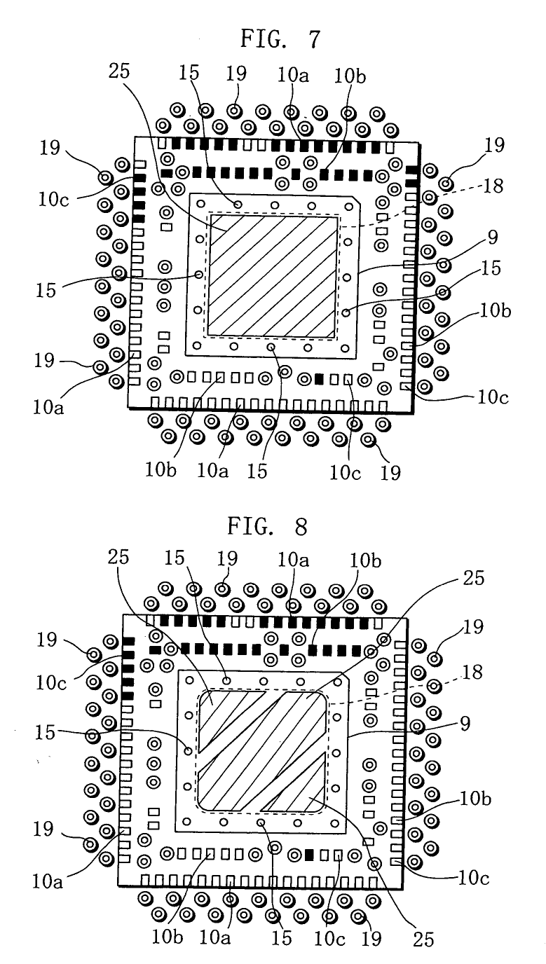

A land grid array package was fabricated in the same manner as in Example 1 above except that, as illustrated in FIG. 7, gas-vent through holes 15 were formed only in a periphery (outside the soldering region 18) of the substrate-side ground electrode 9 and that solder paste 25 was applied in a region inside the gas-vent through holes 15.

The land grid array package thus fabricated is hereafter referred to as Comparative Package X.

### COMPARATIVE EXAMPLE 2

A land grid array package was fabricated in the same manner as in Comparative Example 1 above except that, as illustrated in FIG. 8, solder paste 25 was applied so as to form three separate regions.

The land grid array package thus fabricated is hereafter referred to as Comparative Package Y.

Experiment

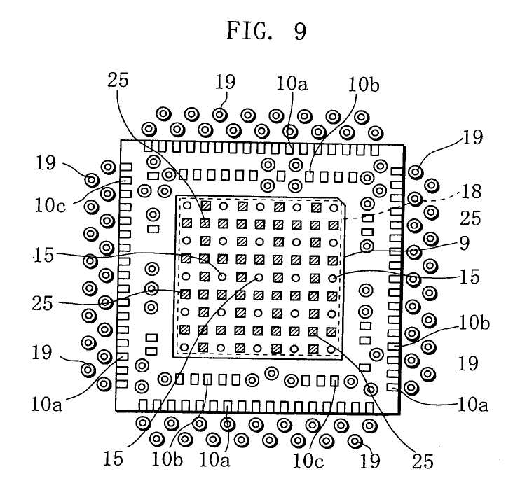

Whether or not disconnections or short circuits occurred in the foregoing Packages A to C of the invention and Comparative Packages X and Y was studied, and the results are shown in FIGS. 5 to 9. The results of the experiments for Packages B and C of the invention as well as Comparative Packages X and Y are shown also in the respective drawings used for explanation thereof, and the result for Package A of the invention is shown in FIG. 9. In each of the drawings, the electrodes at which disconnections or short circuits occurred are filled in with black.

As clearly seen from FIG. 9, no disconnection or short circuit occurred in Package A of the invention, and likewise, as clearly seen from FIGS. 5 and 6, although some disconnections or short circuits occurred in Packages B and C of the invention, the number was very small. In contrast, as clearly seen from FIGS. 7 and 8, it was found that numerous disconnections or short circuits occurred in Comparative Packages X and Y.

It is believed that these results are attributed to the following reason. Specifically, in Comparative Package X, the gas-vent through holes 15 exist only outside of the soldering region 18 and therefore the gas generated during solder reflow is not discharged smoothly. Moreover, since on the substrate-side ground electrode 9 there is only one large area in which the solder paste 25 is applied, the surface tension of the solder paste 25 is large. Therefore, the IC chip is mounted inclined with respect to the package substrate, and consequently, short circuits and disconnections occur between the device-side peripheral electrodes 7 and the substrate-side peripheral electrodes 10. Likewise, in Comparative Package Y, the surface tension of the solder paste 25 is still large although the solder paste 25 is divided into three regions, and moreover, the gas-vent through holes 15 exist only outside of the soldering region 18; therefore, short circuits and disconnections between the device-side peripheral electrodes 7 and the substrate-side peripheral electrodes 10 are not sufficiently prevented from occurring.

In contrast, Packages A to C of the invention have the gas-vent through holes 15 existing within the soldering region 18, and therefore, the gas generated during solder reflow is discharged smoothly. Nevertheless, with Packages B and C of the invention, since there are cases in which the solder paste 25 is applied over gas-vent through holes 15, gas may not be discharged smoothly, and moreover, since each solder paste-applied area is large, the surface tension of the solder paste 25 is large. For this reason, it is possible that short circuits and disconnections occur between the device-side peripheral electrodes 7 and the substrate-side peripheral electrodes 10. In addition, the solder paste 25 may come out to the back side through gas-vent through holes 15, which can also become a cause of short circuits. However, Package A of the invention can prevent the solder paste 25 from being applied over the gas-vent through holes 15 and can discharge the gas smoothly; moreover, since each solder paste-applied area is small, the surface tension of the solder paste is small. This makes it possible to reliably prevent short circuits and disconnections from occurring between the device-side peripheral electrodes 7 and the substrate-side peripheral electrodes 10. In addition, the solder paste 25 does not come out to the back side through the gas-vent through holes 15.

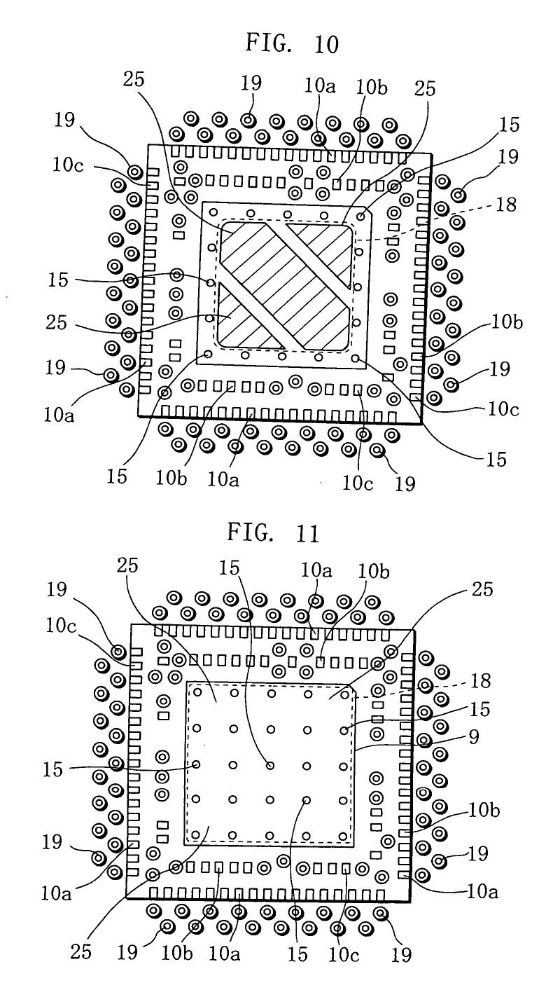

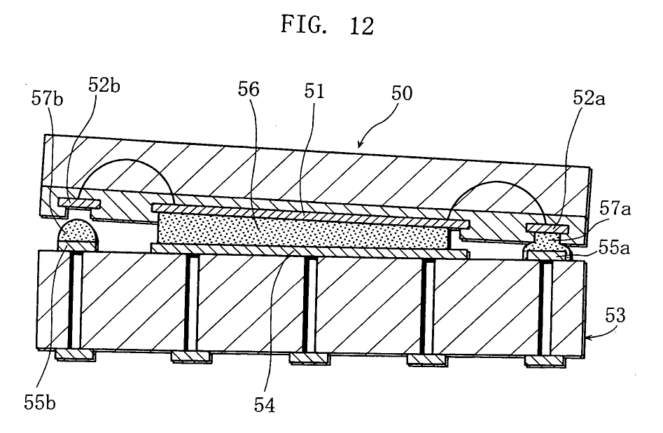

It should be noted that the same tendencies as those described above were confirmed when solder paste 25 was applied as illustrated in FIG. 10 (Comparative Example) and FIG. 11 (the present invention), although the results of the experiments are not illustrated.

Miscellaneous

(1) In the foregoing examples, a high-frequency IC chip was illustrated as an example of the semiconductor device, but the present invention is not limited for high-frequency IC chips.

(2) In the foregoing examples, although the shape of the gas-vent through holes has been described to be tubular, the shape is not limited to this and may be in a cuboid-shaped tube form, a triangular prism-shaped tube form, or the like. The shape of the solder paste applied is not limited to a squared shape either and may be a triangular shape or the like.

(3) The proportion of the gas-vent through holes to the substrate-side ground electrode is not limited to the above-mentioned proportion; however, if the proportion is too large, the application area of solder paste becomes small, reducing the soldering strength between the device-side ground electrode and the substrate-side ground electrode, whereas if the proportion is too small, gas does not goes out smoothly, causing the IC chip to be mounted inclined with respect to the package substrate and short circuits and disconnections to occur between the device-side peripheral electrodes and the substrate-side peripheral electrodes. Therefore, it is desirable that restriction is made within a range in which the above-described problem does not arise.

### INDUSTRIAL APPLICABILITY

As described above, the present invention makes it possible to provide a land grid array package that can prevent short circuits and disconnections from occurring.

1. A land grid array package comprising a semiconductor device in which a device-side center electrode is formed in a substantially central region of its back side and a plurality of device-side peripheral electrodes are formed in a periphery of the device-side center electrode, and a package substrate in which a substrate-side center electrode is provided at a position corresponding to the device-side center electrode and a plurality of substrate-side peripheral electrodes are formed at positions that are in a periphery of the substrate-side center electrode and correspond to the device-side peripheral electrodes, the device-side center electrode and the device-side peripheral electrodes being soldered to the substrate-side center electrode and the substrate-side peripheral electrodes, respectively, by one or more soldered portions, the land grid array package characterized in that: one or more gas-vent through holes passing through the package substrate are formed within a soldering region of the substrate-side center electrode.

2. The land grid array package according to claim 1, wherein the soldered portion in which the device-side center electrode and the substrate-side center electrode are soldered exists at a location within the soldering region other than a location in which the one or more gas-vent through holes exist.

3. The land grid array package according to claim 2, wherein the one or more gas-vent through holes are a plurality of gas-vent through holes and arranged within the soldering region so that their distribution density becomes uniform, and the one or more soldered portions are a plurality of soldered portions and are arranged within the soldering region so that their distribution density becomes uniform.

4. The land grid array package according to claim 3, wherein the gas-vent through holes and the soldered portions are arranged in a substantially grid pattern within the soldering region.

5. The land grid array package according to claim 1, wherein the semiconductor device is a high-frequency IC chip.

6. The land grid array package according to claim 1, wherein the device-side center electrode and the substrate-side center electrode are ground electrodes.

7. The land grid array package according to claim 1, wherein each of the device-side peripheral electrodes and the substrate-side peripheral electrodes are composed of power supply electrodes, ground electrodes, or signal electrodes.

8. The land grid array package according to claim 1, wherein the one or more soldered portions are formed so as to have substantially the same size as the size of the substrate-side peripheral electrodes.

9. The land grid array package according to claim 2, wherein the semiconductor device is a high-frequency IC chip.

10. The land grid array package according to claim 3, wherein the semiconductor device is a high-frequency IC chip.

11. The land grid array package according to claim 4, wherein the semiconductor device is a high-frequency IC chip.

12. The land grid array package according to claim 2, wherein the device-side center electrode and the substrate-side center electrode are ground electrodes.

13. The land grid array package according to claim 3, wherein the device-side center electrode and the substrate-side center electrode are ground electrodes.

14. The land grid array package according to claim 4, wherein the device-side center electrode and the substrate-side center electrode are ground electrodes.

15. The land grid array package according to claim 2, wherein each of the device-side peripheral electrodes and the substrate-side peripheral electrodes are composed of power supply electrodes, ground electrodes, or signal electrodes.

16. The land grid array package according to claim 3, wherein each of the device-side peripheral electrodes and the substrate-side peripheral electrodes are composed of power supply electrodes, ground electrodes, or signal electrodes.

17. The land grid array package according to claim 4, wherein each of the device-side peripheral electrodes and the substrate-side peripheral electrodes are composed of power supply electrodes, ground electrodes, or signal electrodes.

18. The land grid array package according to claim 2, wherein the one or more soldered portions are formed so as to have substantially the same size as the size of the substrate-side peripheral electrodes.

19. The land grid array package according to claim 3, wherein the one or more soldered portions are formed so as to have substantially the same size as the size of the substrate-side peripheral electrodes.

20. The land grid array package according to claim 4, wherein the one or more soldered portions are formed so as to have substantially the same size as the size of the substrate-side peripheral electrodes.
